(19) United States
(12) Patent Application Publication
(10) Pub. No.: US 2010/0090212 A1
(43) Pub. Date: Apr. 15, 2010

(54) MEMORY CELL

(75) Inventor: Chia-Chieh Chang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/641,326

(22) Filed: Dec. 18, 2009

Related U.S. Application Data
(63) Continuation-in-part of application No. 12/126,046, filed on May 23, 2008.

(30) Foreign Application Priority Data
Apr. 28, 2008 (TW) 97115514

(51) Int. Cl. H01L 51/10; H01L 29/792; H01L 21/336

(52) U.S. Cl. 257/40; 438/591; 438/287; 257/E21.423; 257/E51.007; 257/E29.309

(57) ABSTRACT

A memory cell comprising a metal-insulator-semiconductor (MIS) structure is disclosed using a homogeneous carrier trapping layer interposed between a semiconductor layer and the gate electrode of a transistor structure so that the operation voltage is reduced and the manufacturing is simplified with lowered cost. The MIS structure comprises: a gate electrode; a semiconductor layer; and a homogeneous carrier trapping layer interposed between the gate electrode and the semiconductor layer; wherein the homogeneous carrier trapping layer comprises novolac.

### CROSS-REFERENCE TO RELATED APPLICATION

This application is a continuation-in-part of and claims the priority benefit of patent application Ser. No. 12/126,046, filed on May 23, 2008, now pending, which claims the priority benefit of Taiwan application serial no. 97115514, filed on Apr. 28, 2008. The entirety of each of the above-mentioned patent applications is hereby incorporated by reference herein and made a part of this specification.

### BACKGROUND OF THE INVENTION

1. Field of the Invention

The present invention generally relates to a memory cell and, more particularly, to a memory cell using a homogeneous carrier trapping layer interposed between a semiconductor layer and the gate electrode of a transistor structure.

2. Description of the Prior Art

Conventional semiconductor memories such as read-only memories (ROM's) and random access memories (RAM's) are manufactured by complicated semiconductor processing technology with expensive facilities due to the necessary high temperature processing. For ferroelectric ceramic memories, the processing conditions require processing at temperatures in excess of about 600 degrees Celsius. Compared to these expensive inorganic counterparts, organic memories have attracted a great deal of attention because of the remarkable progress in organic electronics and the unique advantages over inorganic memories. For example, organic memories are lightweight and the organic materials are inexpensive and capable of being printed ubiquitously onto plastic substrates.

In order to achieve an ideal organic memory device that is fast, non-volatile and inexpensive, many type of organic memories have been developed. In Adv. Mater. 2006, 18, 3179-3183, Baeg et al. reports an organic non-volatile memory based on pentacene field-effect transistors using a polymeric gate electret. In this paper, a thin layer of poly(α-methylstyrene) (PαMS) interposed between the silicon dioxide gate dielectric layer and the pentacene channel layer is used as a charge storage layer.

In Adv. Mater. 2005, 17, 2692-2695, Naber et al. reports an organic field-effect transistor with programmable polarity. In this paper, poly(vinylidene fluoride/trifluoroethylene) (P(VDF/TrFE)) copolymer is used as the gate dielectric layer. However, such an organic ferroelectric insulator is expensive and the operation voltage of the device using the organic ferroelectric insulator is very high.

Moreover, in U.S. Pat. No. 6,812,509, Xu discloses an organic ferroelectric memory cell. In this patent, ferroelectric polymer such as P(VDF/TrFE) is also used as the gate dielectric layer. Again, such an organic ferroelectric insulator is expensive and the operation voltage of the device using the organic ferroelectric insulator is very high.

In U.S. Publication 2007/0096079, organic thin film transistor (TFT) has been disclosed, as shown in FIG. 1. FIG. 1 is a schematic sectional view of a conventional organic semiconductor device as the FET. Reference numeral 1 denotes a substrate, 2 a gate electrode, 3 a gate insulating layer, 4 a source electrode, 5 a drain electrode, and 6 an organic semiconductor layer. In this conventional device, the gate electrode 2 is formed on the surface of the substrate 1, the gate insulating layer 3 is formed on the gate electrode 2, and the source electrode 4 and the drain electrode 5 are formed on the surface of the gate insulating layer 3 with a space therebetween. The organic semiconductor layer 6 is formed on the source electrode 4, the drain electrode 5 and the gate insulating layer 3, the space between these electrodes, in contact with the both electrodes 4 and 5. The gate insulating layer 3 is formed to cover the gate electrode 2.

In the above conventional organic TFT, although the gate insulating layer 3 can be formed by novolac material to reduce the leakage current occurring at the gate insulating layer 3 within arrange of 0-20 V, the novolac material for the gate insulating layer 3 is not for the use in memory based on capacitance properties. Basically, the novolac with polyvinyl phenol (PVP) has a large weight percentage of PVP to propylene glycol monomethyl ether acetate (PGMEA), usually larger than 10% in several examples such as 5.9 g of phenolic novolac to 54 g of PFMEA. The concerning of the novolac for the gate insulating layer 3 is for reducing the leakage current.

Even further, U.S. Pub. 2008/0121871 has also disclosed the use of PVP for the polymer dielectric material in concerning the current density to be endured. The weight percentage of PVP to PGMEA is also 10%.

In other words, although the PVP material structure has been proposed in prior art, the compositions of those PVP materials are all used in TFT dielectric layer to prevent carrier such as electrons and holes into the semiconductor layer to cause the uncontrolled current. As a result, PVP material is easy and cheap to use for TFT dielectric layer but not for use as memory device.

### SUMMARY OF THE INVENTION

In an aspect of the invention, a memory cell uses a homogeneous carrier trapping layer interposed between a semiconductor layer and the gate electrode of a transistor structure to achieve simplified manufacturing with lowered cost.

In an aspect, the present invention provides a memory cell comprising a metal-insulator-semiconductor (MIS) structure, the MIS structure comprising: a gate electrode; a semiconductor layer; and a homogeneous carrier trapping layer interposed between the gate electrode and the semiconductor layer; wherein the homogeneous carrier trapping layer comprises novolac. The novolac is a mixture of materials comprising poly-4-vinyl phenol (PVP) and propylene glycol monomethyl ether acetate (PGMEA) and has a weight percentage of PVP dissolved in PGMEA smaller than or equal to 8%.

In an aspect, the present invention provides a method for fabricating memory cell having a metal insulator semiconductor (MIS) structure, the MIS structure comprising: a gate electrode; a semiconductor layer; and a homogeneous carrier trapping layer interposed between the gate electrode and the semiconductor layer, wherein the homogeneous carrier trapping layer comprises novolac. The method comprises forming the novolac by mixing materials comprising poly-4-vinyl phenol (PVP) and propylene glycol monomethyl ether acetate (PGMEA) wherein a weight percentage of PVP dissolved in PGMEA is smaller than or equal to 8%.

### BRIEF DESCRIPTION OF THE DRAWINGS

The objects, spirits and advantages of the preferred embodiments of the present invention will be readily understood by the accompanying drawings and detailed descriptions as follows.

FIG. 1 is a cross-sectional view, schematically illustrating a conventional organic TFT.

FIG. 2A is a cross-sectional diagram showing a memory cell in a first embodiment of the present invention.

FIG. 2B is a graph showing the C-V measurement for the memory cell in FIG. 2A.

FIG. 3 is a cross-sectional diagram showing a memory cell in a second embodiment of the present invention.

FIG. 4 is a cross-sectional diagram showing a memory cell in a third embodiment of the present invention.

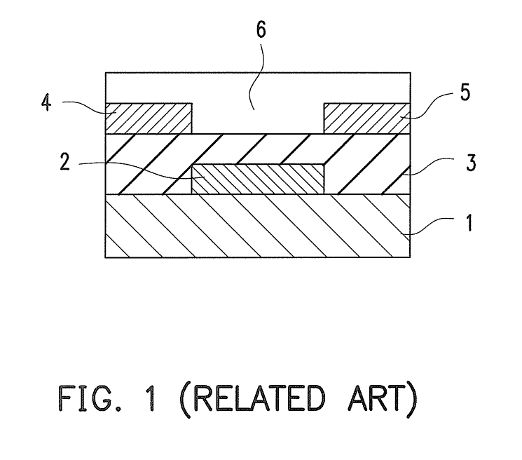

### DETAILED DESCRIPTION OF THE PREFERRED EMBODIMENT

The present invention providing a memory cell can be exemplified by the preferred embodiments as described hereinafter.

The memory cell based on TFT structure usually needs a carrier trapping layer. The present invention proposes to use the novolac material to form the TFT itself as memory cell. In order to have the memory property, there is need in providing a memory cell using a homogeneous carrier trapping layer interposed between a semiconductor layer and the gate electrode of a transistor structure so that the operation voltage is reduced and the manufacturing is simplified with lowered cost. In considering the composition of PVP with a memory function, contrary to the prior art, the low composition of PVP may result some trapping centers to store carriers, such as electrons and holes. The induced current in the semiconductor layer by the electric field created from the gate voltage can be controllable due to the injection and removing carriers of the PVP layer. Those processes can be called “write” and “erase” operations to form a memory. The present invention proposes a recipe of novolac material used as trapping layer in memory device instead of dielectric layer in TET device.

In the present invention, there is provided a memory cell using a homogeneous carrier trapping layer interposed between a semiconductor layer and the gate electrode of a transistor structure so that a clear hysteresis loop is observed in C-V (capacitance-voltage) measurement of the memory cell. From the viewpoint of memory, the memory cell of the present invention, the operation voltage is reduced and the manufacturing is simplified with lowered cost.

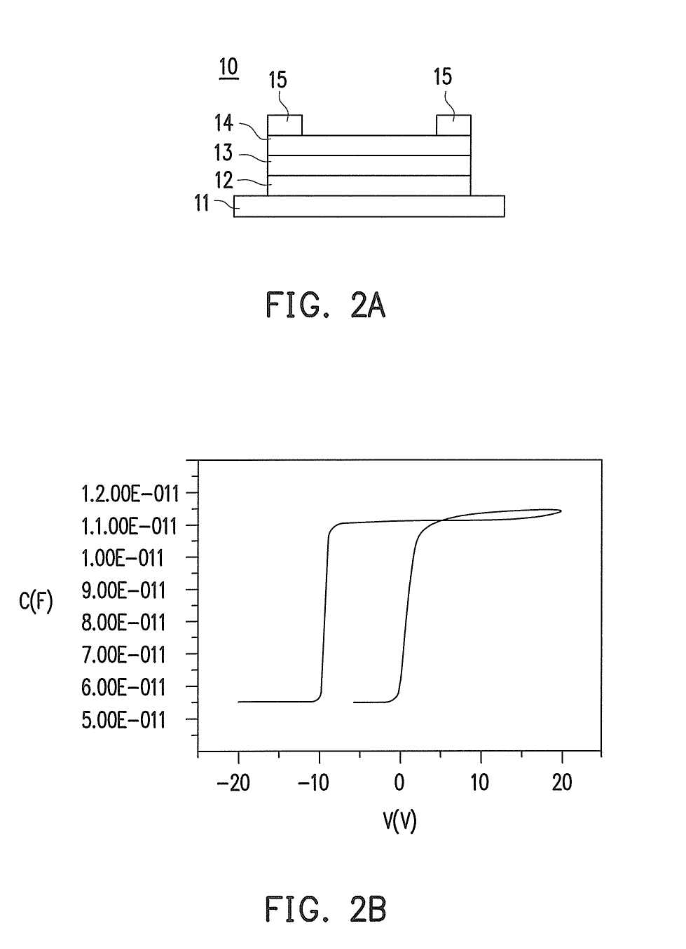

Please refer to FIG. 2A, which is a cross-sectional diagram showing a memory cell in a first embodiment of the present invention. In FIG. 2A, a memory cell 10 uses a field-effect transistor (FET) structure. As all of the individual processing steps are well known in the art, the following description will proceed by focusing on the structure and materials choices for the memory cell and variations in these.

The memory cell 10 is constructed on a substrate 11, which can be either a rigid or flexible substrate. The substrate 11 may comprise a variety of materials having a substantially smooth surface. In the present embodiment, the substrate 11 comprises plastic, semiconductor, metal or glass.

On the upper surface of the substrate 11, a gate electrode 12 is formed. The gate electrode 12 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

A homogeneous carrier trapping layer 13 is formed on the upper surface of the gate electrode 12. In the present embodiment, the homogeneous carrier trapping layer 13 comprises novolac. More particularly, the novolac is prepared by a cross-linking reaction in a mixture comprising an organic compound, a cross-linking agent and a solvent. For example, the organic compound comprises poly-4-vinyl phenol (PVP) that can be cross-linked by the cross-linking agent. The cross-linking agent comprises organic phenolic monomer capable of performing a condensation reaction, such as poly melamine-co-formaldehyde (PMF). The solvent comprises a material selected from a group consisting of ester, ketone, and acetate. For example, the solvent comprises propylene glycol monomethyl ether acetate (PGMEA). The ratio for PVP to PMF is 2:1 and the weight percentage for PVP dissolved in PGMEA is smaller than or about equal to 8%, or even less. For example, it can be 7%, 5% or less. The thickness of the homogeneous carrier trapping layer 13 is in the range from approximately 10 nm to approximately 1000 nm.

It can be noted that the weight percentage for PVP for the conventional organic transistor need high percentage, so as to let the gate dielectric layer to endure the voltage applied on the gate electrode and thereby reduce the leakage current into the channel of the transistor. However, if the transistor is used as a memory, the weight percentage for PVP is controlled at relative low level, so that the carriers in the gate electrode can enter the gate dielectric layer and cause the change of the channel current. Since this change of channel current is controllable due to the hysteresis loop in C-V relation as described in FIG. 2B, the transistor used as a memory cell is possible. The aspect of the invention is to form the memory cell based on the transistor itself but writing different capacitance levels at the gate dielectric layer. Due to the novolac with the preparation, the transistor itself can be a memory cell as well.

Then, on the upper surface of the homogeneous carrier trapping layer 13 is formed a semiconductor layer 14. In the present embodiment, the semiconductor layer 14 comprises solid-state semiconductor (for example, Si, GaAs and ZnO) or organic semiconductor (for example, poly(phenylenes), thiophene oligomers, pentacene, polythiophene, and perfluoro copper phthalocyanine). There materials can be formed by conventional processes such as thermal growth, sputtering, chemical vapor deposition, solution deposition or printing.

On the top surface of the semiconductor layer 14, two source/drain electrodes 15 are formed spaced apart with a space therebetween to define a channel region for a field-effect transistor. The source/drain electrodes 15 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

FIG. 2B is a graph showing the C-V measurement for the memory cell in FIG. 2A. In FIG. 2B, a clear C-V hysteresis loop is demonstrated, when the operating voltage varies from −20V to 20V and the capacitance ranges from 50 pF to 110 pF at 500 kHz. The hysteresis remains unchanged in the scanning direction from positive to negative voltage and vice versa. It is believed that a wide range of hysteresis enables favorable read/write characteristics of the memory cell. In this embodiment, the PVP material was composed with the crosslink agent PMF in a ratio 2:1 and with the organic solvent PGMEA in a ratio of 4%.

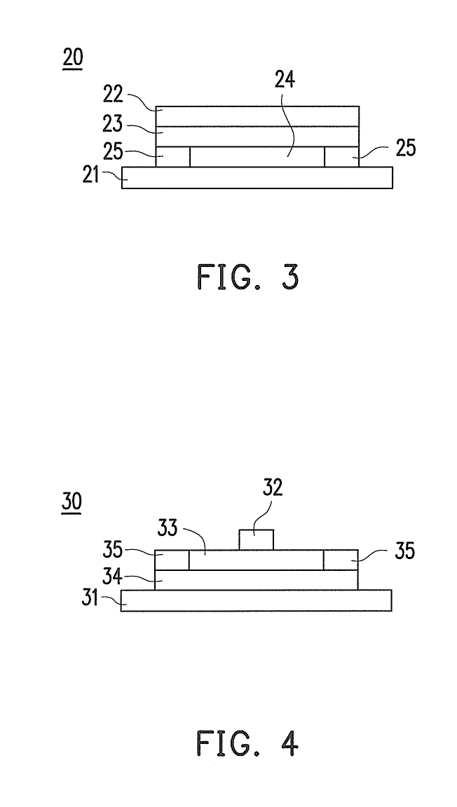

The present invention is exemplified by but not restricted to the first embodiment. For example, FIG. 3 is a cross-sectional diagram showing a memory cell in a second embodiment of the present invention. In FIG. 3, a memory cell 20 uses a field-effect transistor (FET) structure. As all of the individual processing steps are well known in the art, the following description will proceed by focusing on the structure and materials choices for the memory cell and variations in these.

The memory cell 20 is constructed on a substrate 21, which can be either a rigid or flexible substrate. The substrate 21 may comprise a variety of materials having a substantially smooth surface. In the present embodiment, the substrate 21 comprises plastic, semiconductor, metal or glass.

On the upper surface of the substrate 21, two source/drain electrodes 25 are formed spaced apart with a space therebetween to define a channel region for a field-effect transistor. The source/drain electrodes 25 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

A semiconductor layer 24 is formed between the two source/drain electrodes 25. In the present embodiment, the semiconductor layer 24 comprises solid-state semiconductor (for example, Si, GaAs and ZnO) or organic semiconductor (for example, poly(phenylenes), thiophene oligomers, pentacene, polythiophene, and perfluoro copper phthalocyanine). There materials can be formed by conventional processes such as thermal growth, sputtering, chemical vapor deposition, solution deposition or printing.

On the upper surface of the semiconductor layer 24, a homogeneous carrier trapping layer 23 is formed. In the present embodiment, the homogeneous carrier trapping layer 23 comprises novolac. More particularly, the novolac is prepared by a cross-linking reaction in a mixture comprising an organic compound, a cross-linking agent and a solvent. For example, the organic compound comprises poly-4-vinyl phenol (PVP) that can be cross-linked by the cross-linking agent. The cross-linking agent comprises organic phenolic monomer capable of performing a condensation reaction, such as poly melamine-co-formaldehyde (PMF). The solvent comprises a material selected from a group consisting of ester, ketone, and acetate. For example, the solvent comprises propylene glycol monomethyl ether acetate (PGMEA). The ratio for PVP to PMF is 2:1 and the weight percentage for PVP dissolved in PGMEA is smaller than 16% and preferably smaller than or about equal to 8%. The thickness of the homogeneous carrier trapping layer 13 is in the range from approximately 10 nm to approximately 1000 nm.

A gate electrode 22 is formed on the upper surface of the homogeneous carrier trapping layer 23. The gate electrode 22 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

The present invention is exemplified by but not restricted to the first and the second embodiments. For example, FIG. 4 is a cross-sectional diagram showing a memory cell in a third embodiment of the present invention. In FIG. 4, a memory cell 30 uses a field-effect transistor (FET) structure. As all of the individual processing steps are well known in the art, the following description will proceed by focusing on the structure and materials choices for the memory cell and variations in these.

The memory cell 30 is constructed on a substrate 31, which can be either a rigid or flexible substrate. The substrate 31 may comprise a variety of materials having a substantially smooth surface. In the present embodiment, the substrate 31 comprises plastic, semiconductor, metal or glass.

On the upper surface of the substrate 31, a semiconductor layer 34 is formed. In the present embodiment, the semiconductor layer 34 comprises solid-state semiconductor (for example, Si, GaAs and ZnO) or organic semiconductor (for example, poly(phenylenes), thiophene oligomers, pentacene, polythiophene, and perfluoro copper phthalocyanine). There materials can be formed by conventional processes such as thermal growth, sputtering, chemical vapor deposition, solution deposition or printing.

On the top surface of the semiconductor layer 34, two source/drain electrodes 35 are formed spaced apart with a space therebetween to define a channel region for a field-effect transistor. The source/drain electrodes 35 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

A homogeneous carrier trapping layer 33 is formed between the two source/drain electrodes 35. In the present embodiment, the homogeneous carrier trapping layer 33 comprises novolac. More particularly, the novolac is prepared by a cross-linking reaction in a mixture comprising an organic compound, a cross-linking agent and a solvent. For example, the organic compound comprises poly-4-vinyl phenol (PVP) that can be cross-linked by the cross-linking agent. The cross-linking agent comprises organic phenolic monomer capable of performing a condensation reaction, such as poly melamine-co-formaldehyde (PMF). The solvent comprises a material selected from a group consisting of ester, ketone, and acetate. For example, the solvent comprises propylene glycol monomethyl ether acetate (PGMEA). The ratio for PVP to PMF is 2:1 and the weight percentage for PVP dissolved in PGMEA is smaller than 16%, and preferably smaller than or about equal to 8%. The thickness of the homogeneous carrier trapping layer 13 is in the range from approximately 10 nm to approximately 1000 nm.

A gate electrode 32 is formed on the upper surface of the homogeneous carrier trapping layer 33. The gate electrode 32 can comprise a variety of conductive materials such as metal (for example, gold, platinum, aluminum and titanium), conductive oxides (for example, ITO), conductive polymers (for example, polyaniline, and polypyrrol) or combination thereof. There materials can be formed by conventional processes such as thermal growth, sputtering, chemical vapor deposition, solution deposition or printing.

According to the above discussion, it is apparent that the present invention discloses a memory cell using a homogeneous carrier trapping layer interposed between a semiconductor layer and the gate electrode of a transistor structure so that the operation voltage is reduced and the manufacturing is simplified with lowered cost. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A memory cell comprising a metal-insulator-semiconductor (MIS) structure, the MIS structure comprising:
a gate electrode;
a semiconductor layer; and
a homogeneous carrier trapping layer interposed between the gate electrode and the semiconductor layer, wherein the homogeneous carrier trapping layer comprises novolac, wherein the novolac is a mixture of materials comprising poly-4-vinyl phenol (PVP) and propylene glycol monomethyl ether acetate (PGMEA) and has a weight percentage of PVP dissolved in PGMEA smaller than or about equal to 8%.

2. The memory cell as recited in claim 1, wherein the gate electrode comprises a conductive material selected from a group consisting of metal, conductive oxide, conductive polymer and combination thereof.

3. The memory cell as recited in claim 1, wherein the semiconductor layer comprises a semiconducting material selected from a group consisting of solid-state semiconductor and organic semiconductor.

4. The memory cell as recited in claim 1, wherein the novolac is prepared by a cross-linking reaction in a mixture comprising an organic compound, a cross-linking agent and a solvent.

5. The memory cell as recited in claim 4, wherein the organic compound comprises poly-4-vinyl phenol (PVP).

6. The memory cell as recited in claim 4, wherein the cross-linking agent comprises organic phenolic monomer capable of performing a condensation reaction.

7. The memory cell as recited in claim 6, wherein the cross-linking agent comprises poly melamine-co-formaldehyde (PMF).

8. The memory cell as recited in claim 4, wherein the solvent comprises a material selected from a group consisting of ester, ketone, and acetate.

9. The memory cell as recited in claim 8, wherein the solvent comprises propylene glycol monomethyl ether acetate (PGMEA).

10. The memory cell as recited in claim 1, wherein the novolac is prepared by a cross-linking reaction in the mixture, the mixture further comprises poly melamine-co-formaldehyde (PMF).

11. The memory cell as recited in claim 10, wherein a ratio of PVP to PMF is 2:1.

12. The memory cell as recited in claim 1, further comprising a pair of source/drain electrodes electrically coupled to the semiconductor layer.

13. The memory cell as recited in claim 12, wherein the pair of source/drain electrodes are disposed on the semiconductor layer.

14. The memory cell as recited in claim 12, wherein the pair of source/drain electrodes are embedded in the semiconductor layer.

15. The memory cell as recited in claim 12, wherein the pair of source/drain electrodes comprise a conductive material selected from a group consisting of metal, conductive oxide, conductive polymer and combination thereof.

16. A method for fabricating memory cell having a metal insulator semiconductor (MIS) structure, the MIS structure comprising: a gate electrode; a semiconductor layer; and a homogeneous carrier trapping layer interposed between the gate electrode and the semiconductor layer, wherein the homogeneous carrier trapping layer comprises novolac, the method comprising:
forming the novolac by mixing materials comprising poly-4-vinyl phenol (PVP) and propylene glycol monomethyl ether acetate (PGMEA) wherein a weight percentage of PVP dissolved in PGMEA is smaller than or about equal to 8%.

17. The method of claim 16, wherein the step of forming the novolac is making a cross-linking reaction in a mixture comprising PVP, PGMEA, and further poly melamine-co-formaldehyde (PMF).

18. The method of claim 17, wherein a ratio of PVP to PMF is 2:1.

19. The method of claim 17, wherein the weight percentage of PVP dissolved in PGMEA is smaller than or about equal to 7%.
